(19) United States
(12) Patent Application Publication
(10) Pub. No.: US 2024/0275349 A1
(43) Pub. Date: Aug. 15, 2024

(54) VARIABLE GAIN AMPLIFIER-BASED OUTPUT CURRENT CONTROL

(71) Applicant: Litrinium, Inc., Mission Viejo, CA (US)

(72) Inventors: Kashif Ahmed, Tustin, CA (US); Jichun Zhang, Irvine, CA (US)

(21) Appl. No.: 18/169,768

(22) Filed: Feb. 15, 2023

(51) Int. Cl. H03G 3/30; H01S 5/042

(52) U.S. Cl. CPC H03G 3/30; H01S 5/042; H03G 2201/103

(57) ABSTRACT

A laser driver chipset for providing a signal to a laser diode is described. The laser driver chipset has a variable gain amplifier (VGA) circuit and a laser driver circuit. The VGA circuit is configured to receive an input signal having a variable swing amplitude and modulate it to produce a fixed swing amplitude. The laser driver circuit is configured to receive a VGA output signal from the VGA circuit and generate a linear output response to the input signal such that it provides an output current to drive the laser diode. The VGA circuit can comprise a first loop for biasing the direct current level to a target direct current level and a second loop for modulating the variable swing amplitude of the input signal to produce a fixed swing amplitude.

### FIELD OF THE INVENTION

The field of the invention is signal processing.

### BACKGROUND

The inventive concepts herein aim to use a variable gain amplifier (VGA) in the predriver stage to automatically modify a predriver output swing to the value needed by a driver to supply a desired modulation current.

In an optical communication link, light passing through an optical output is generated by a LASER (“laser”). For example, the optical signal can be generated by laser diodes, which can include any device that converts electrical energy into light (e.g., semiconductor-based laser diode). Lasers modulate the light depending of the current it is receiving using a modulation and bias current. Modulation currents modulate the light while bias current provides the DC or average value. Depending of the type of laser, the amount of modulation current can vary. In some embodiments, the modulation current can be very large (from 1 mA up to 100 mA.

The modulation current is provided by a laser driver, which converts the electrical signal received from an upstream device in a voltage domain into the current domain. The electrical signal from the voltage domain is converted to the current domain by a laser driver which provides a modulation and a bias current.

In most instances, the output swing of the electrical signal from the upstream device is fixed. However, the lasers are sensitive to the external environment, including, for example, changes in temperature. To account for the sensitivity of lasers to the external environments, the user is required to change the amount of modulation current sent to the laser to compensate for variations thereby keeping a constant optical power though an optical output, such as an optical fiber.

The laser driver chip sends the modulation current defined by the user to the laser. The signal path of conventional laser driver chips is composed at least of a predriver and a driver stage. Nowadays, and especially due to the PAM4 signal encoding, the entire signal path has to remain linear. However, the amount of modulation current provided by the driver stage is strongly dependent of the input signal amplitude. The dependency of the modulation current provided by the driver stage on the input signal amplitude adversely affects convention laser driver chips. As such, conventional laser driver chips may require a user to manually retune upstream device output swings in order to allow the driver stage to produce maximum output current.

There is a need for signal processing systems that can automatically modify an output swing of upstream devices to modify a modulation current, which reduces or removes the burden on a user to manually modify output swings of upstream devices and can reduce power consumption, since the invention described herein makes a maximum upstream output swing unnecessary to have a maximum modulation current value.

U.S. Pat. No. 8,576,903 to Raphaeli teaches a PAM-N feedback equalizer that comprises a coefficient computation unit that includes a feedback unit that uses computed feedback coefficients to mitigate interference from data symbols. Raphaeli further includes an error and decision unit for computing at least an error value with respect to one of a plurality of decision levels. The system provides for “a gain applied to the input signal to bring the level of the input signal to nominal decision levels. This is performed during power-up of the receiver by means of a variable gain amplifier (VGA) 160.” (Raphaeli, col. 2, lines, 33-35). However, Raphaeli teaches only an adaptive method of setting reference voltage levels for a decision feedback equalizer, where the application is on the receiver side. Indeed, Raphaeli fails to contemplate to using VGA for current control, more specifically DML or VCSE laser current control.

U.S. Pat. No. 11,290,307 to Wang discloses many of the same concepts as Rapheali. The usage of a “calibration circuit 170 for a PAM-N receiver” is described in its FIG. 9, where a variable gain amplifier (VGA) control circuit 976 is configured for generation of a gain control signal based on a series of reference voltages. (Wang, col. 7, In. 18-53). Both Wang and Rapheali merely disclose setting the right amplitude and gain for a receiver for optimum voltage strength. Specifically, Wang discusses AFE gain adaptation for a PAM-N receiver, adjusting the PAM-N receiver eye in terms of alignment and reference level. Indeed, Wang discloses VGA control circuits used to control the gain of AFE based on reference voltages from an adaptation FSM. In contrast, the current inventive subject matter is focused on gain output control, while using a VGA with a laser driver.

Raphaeli, Wang, and all other extrinsic materials discussed herein are incorporated by reference to the same extent as if each individual extrinsic material was specifically and individually indicated to be incorporated by reference. Where a definition or use of a term in an incorporated reference is inconsistent or contrary to the definition of that term provided herein, the definition of that term provided herein applies and the definition of that term in the reference does not apply.

Thus, there is still a need for processing systems that are uniquely adapted to automatically upstream output swing to achieve desired modulation currents.

### SUMMARY OF THE INVENTION

The inventive subject matter described herein contemplates a laser driver chipset for providing a signal to a laser diode. The chipset comprises a variable gain amplifier (VGA) circuit configured to receive an input signal that has a variable swing amplitude, and modulate the variable swing amplitude of the input signal to produce a fixed swing amplitude. The chipset also has a laser driver circuit configured to receive a VGA output signal from the VGA circuit and generate a linear output response to the input signal such that it provides an output current to drive the laser diode. In this manner, the chipset provides output current control for the laser diode.

In some embodiments, the driver circuit can be a direct modulation laser (DML) driver circuit. The DML driver circuit receives an VGA output signal from the VGA circuit, converts it to a current proportional to the gain (e.g. transconductance) of the DML driver stage, and drives the laser as its load with the current. In some embodiments, the VGA circuit functions via 1) a first loop for biasing the direct current level of the DML stage to a target direct current level, and 2) a second loop for modulating the variable swing amplitude of the input signal to produce a fixed or user programmed swing amplitude. There are at least two implementations of the inventive subject matter that are designed for two different types of laser: 1) Vertical Cavity Surface Emitting Laser (VCSEL), and 2) Direct Modulated Laser (DML).

Various resources, features, aspects and advantages of the inventive subject matter will become more apparent from the following detailed description of preferred embodiments, along with the accompanying drawing figures in which like numerals represent like components.

### BRIEF DESCRIPTION OF THE DRAWINGS

FIG. 1 is a functional block diagram illustrating a general laser driver of the prior art.

FIG. 2A is a functional block diagram illustrating a general laser driver of the inventive subject matter.

FIG. 2B is a functional block diagram illustrating a regulator of the inventive subject matter.

FIG. 3A is a functional block diagram illustrating a VCSEL target voltage generator of the inventive subject matter.

FIG. 3B is a functional block diagram illustrating a DML target voltage generator of the inventive subject matter

FIG. 4A is a functional block diagram illustrating a VGA detector of the inventive subject matter.

FIG. 4B is a functional block diagram illustrating an alternative view of VGA detector 230.

FIG. 5 is a functional block diagram illustrating one embodiment of the VGA 210 of FIG. 2A.

### DETAILED DESCRIPTION

One should appreciate that the disclosed techniques provide many advantageous technical effects including automatically modifying a predriver output swing to the value needed by a driver to supply a desired modulation current.

The following discussion provides many example embodiments of the inventive subject matter. Although each embodiment represents a single combination of inventive elements, the inventive subject matter is considered to include all possible combinations of the disclosed elements. Thus, if one embodiment comprises elements A, B, and C, and a second embodiment comprises elements B and D, then the inventive subject matter is also considered to include other remaining combinations of A, B, C, or D, even if not explicitly disclosed.

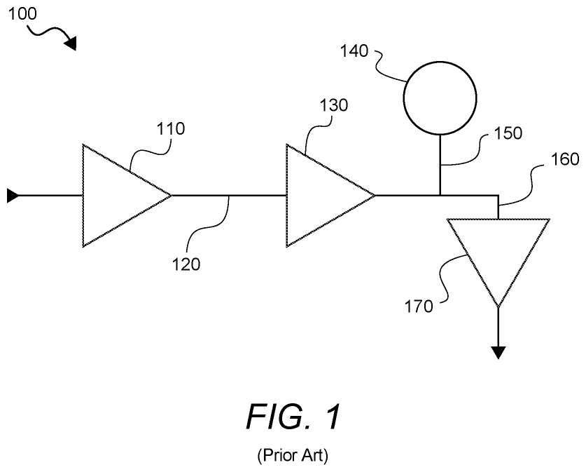

FIG. 1 is a functional block diagram illustrating a general laser driver of the prior art. FIG. 1 depicts a general laser driver system 100 which includes a predriver 110 that drives a laser driver 130, a predriver voltage output 120, a bias current 140 that generates a laser bias 150, and a revised laser current 160 that drives a laser diode 170. The general laser driver system 100 incorporates a pre driver stage with predriver 110, and a laser driver stage with a laser driver 130. In some embodiments, general laser driver system 100 is configured to adjust the gain of the pre driver stages to control signal amplitude of the drive input and thus the laser current.

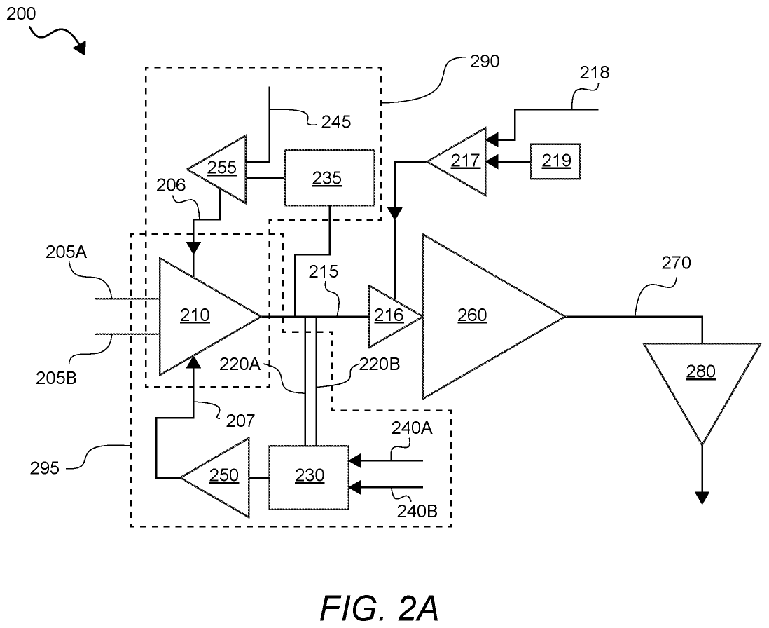

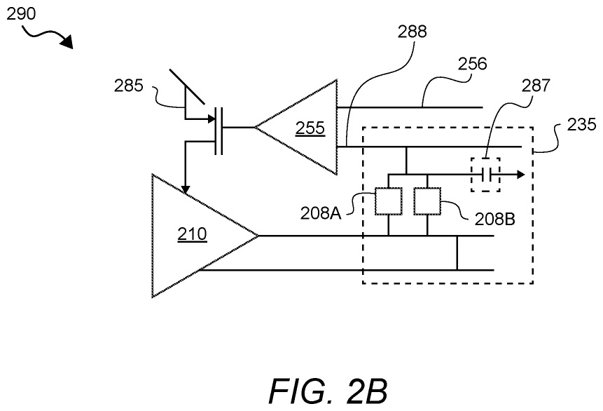

FIG. 2A is a functional block diagram illustrating a general laser driver of the inventive subject matter. FIG. 2A depicts a general laser driver system 200 which includes a input voltage 205A and 205B, a VGA 210 with 1) a common mode regulator loop 290 and 2) a VGA swing control loop 295, which produces a VGA output voltage 215 passed into buffer 216, and a laser driver 260 configured to generate a final laser current 270 to drive laser diode 280. The buffer 216 is configured to receive a current from a regulator 217. The regulator 217 is configured to receive a driver tail current target 218 and a driver tail current sensing 219. In a preferred embodiment, an input swing from input voltage 205A and 205B ranges between 300 mVpp to 1.2 Vpp. In a related embodiment, the VGA output voltage 215 is regulated to a fixed target level, such that the final laser current 270 is maintained to the same level even if the input swing from laser current input 205A and 205B changes over time.

In one embodiment, VGA 210 may include any means of manipulating an electronic signal using passive components. For example, VGA 210 can include any mixture of resistors, capacitors, and inductors to tone an electronic signal. In another embodiment, VGA 210 may include any means of adjusting the balance between frequency components. VGA 210 may be any electronic circuit placed in a laser driver system. In a related embodiment, VGA 210 varies the gain of the input signal to set a value output amplitude with an automatic gain control (AGC) circuitry.

The common mode regulator loop 290 includes the input voltage 205A and 205B as they pass into a CM sensor 235, and a regulator 255 receiving the current from a Vreference voltage 245 and CM sensor 235 to produce a common mode regulator loop output 206. In the depicted embodiment, common mode regulator loop 290 is further configured to pass the common mode regulator loop output 206 into VGA 210. The VGA swing control loop 295 includes the input voltage 205A and 205B as they pass into a detector 230, and a swing control regulator 250 receiving the current from detector 230 to produce a VGA swing control loop output 207. The detector 230 is further configured to receive Vtarget voltage inputs 240A and 240B to be passed into swing control regulator 250. In the depicted embodiment, the VGA swing control loop 295 is further configured to pass the VGA swing control loop output 207 into VGA 210. In a preferred embodiment, the buffer 216 is isolated from the VGA 210 and the VGA swing control loop 295, and is configured to adjust the input voltage 205A and 205B via a regulator 217.

The depicted VGA 210 includes the common mode regulator loop 290 and the VGA swing control loop 295. To optimize the operating condition of the driver stage over process, voltage and temperature (“PVT”), a supply voltage of VGA 210 is regulated such that an output common mode of VGA 210 is controlled. Variable gain amplifier 210 varies the gain depending on a control voltage. Variable gain amplifier 210 is configured to compensate for any swing variation of an input signal from a transmitter. The VGA 210 detects an output swing amplitude using VGA detector 230 and compares it to a target voltage provided by a modulation biasing block of a laser driver (not shown). It is contemplated that the input range can range from 300 mVpp to more than 1 Vpp. In a related embodiment, a laser modulation target value can be programmed by a user via an inter-integrated circuit (“I2C”) communication bus. In a preferred embodiment, the time constant of common mode regulator loop 290 is lower than that of the swing control loop 295. In some embodiments, the time constant of common mode regulator loop 290 is 200 kHz. In related embodiments the time constant of the swing control loop 295 is 6 MHz.

FIG. 2B is a functional block diagram illustrating a regulator of the inventive subject matter. FIG. 2B depicts the regulator 290 which includes a programmable reference voltage 236, the CM sensor 235 which includes rectifiers 208A and 208B, an opamp 255, a supply 285, and the VGA 210. In a preferred embodiment, the CM sensor 235 passes the input voltage 205A and 205B into the rectifiers 208A and 208B across a high speed differential signal (not shown), with the center of the two rectifiers 208A and 208B tapped to the decoupling capacitor 287. The filtered voltage output 288 is the common mode of the VGA output voltage.

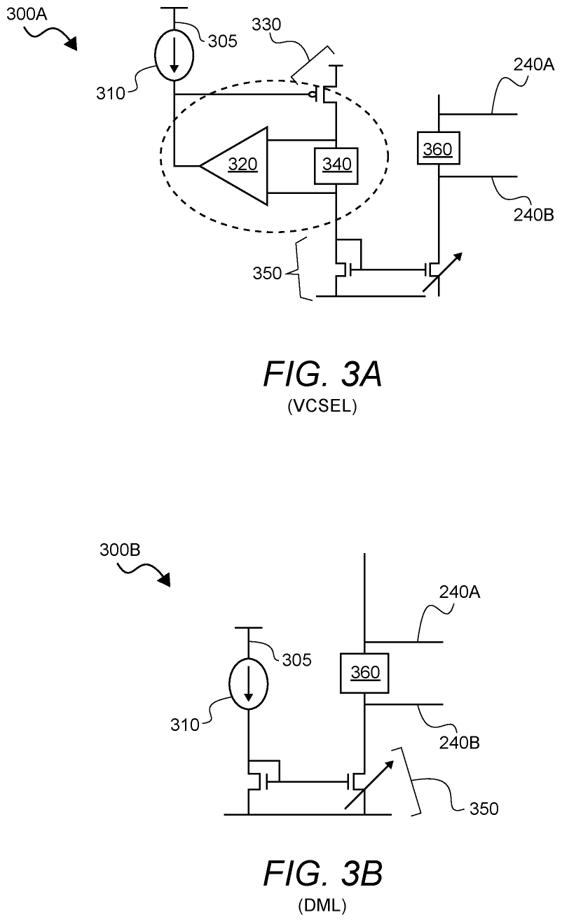

FIG. 3A is a functional block diagram illustrating a VCSEL target voltage generator of the inventive subject matter. FIG. 3A depicts a modulation current target generator 300A which includes an input current 305 passed into Imod target 310, an LD replica 320 with a LD rectifier 340, a P-Channel MOSFET (PFET) 330, a current mirror 350, and a Vtarget rectifier 360 configured to output Vtarget voltage inputs 240A and 240B. In a preferred embodiment, the LD replica 320 provides to VGA 210 a current proportional to the swing control loop output 207. The VGA 210 is configured to convert an amplitude of the input back to a targeted amplitude voltage, using a gain control loop output 207. In some embodiments, a modulation current target generator 300A is anode driven. In other embodiments, a modulation current target generator 300A is cathode driven.

VGA 210 varies the gain depending on a control voltage. Variable gain amplifier 210 is configured to compensate for any swing variation of an input signal from a transmitter.

FIG. 3B is a functional block diagram illustrating a similar target generator as a DML target voltage generator of the inventive subject matter. FIG. 3B depicts a modulation current target generator 300B which includes an input current 305 passed into Imod target 310, a current mirror 350, and a Vtarget rectifier 360 configured to output Vtarget detector voltage 240A and 240B. In a preferred embodiment, the current mirror 350 is a DAC (Digital-to-Analog Convertor) configured to scale the input current 305 up to a certain factor. In certain embodiments, input current 305 ranges from 10 mA to 60-80 mA. In another embodiment, the input current 305 ranges from 1 mA to 10 mA.

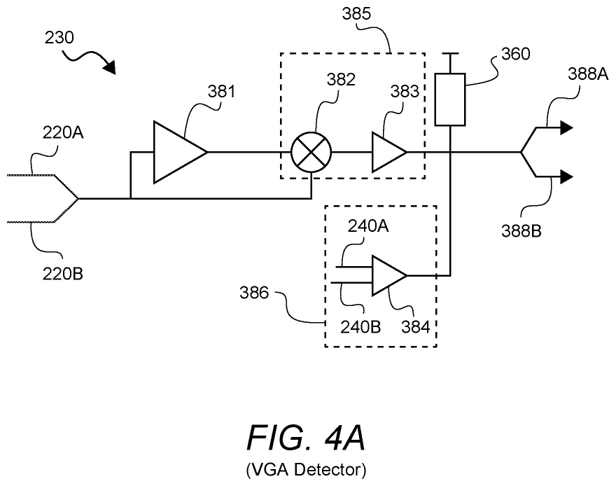

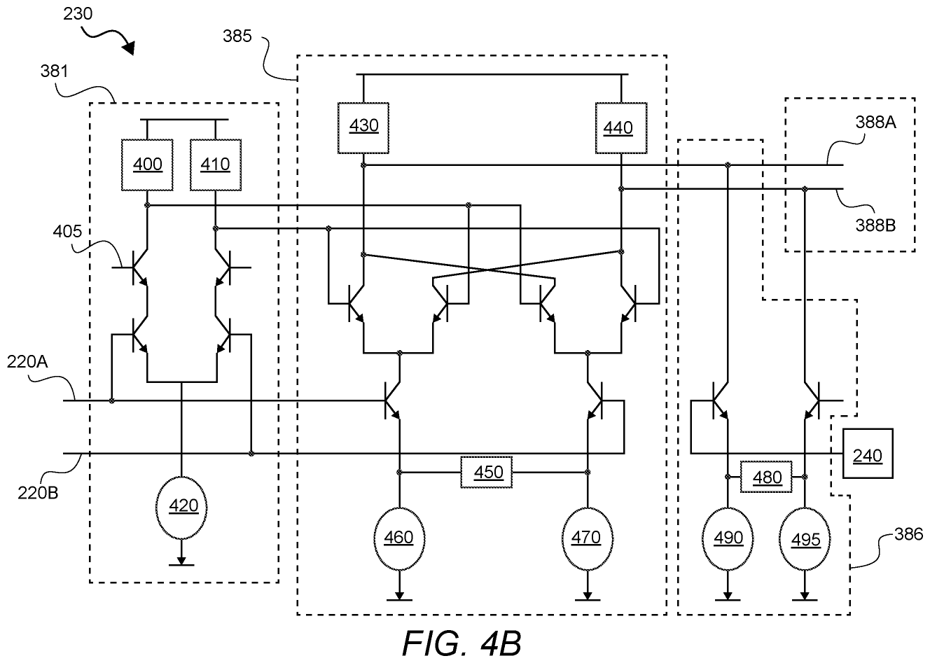

FIG. 4A is a functional block diagram illustrating a VGA detector of the inventive subject matter. FIG. 4A depicts the VGA detector 230 with VGA outputs 220A and 220B, a mixing detector module 385 which includes amplifier 381 and a mixer 382, a VGA output gain modulator 383, a rectifier 360, a Vtarget adjustment module 384 which includes the Vtarget voltage inputs 240A and 240B and Vtarget current gain modulator 386, and a VGA detector output 388. In the depicted embodiment, VGA outputs 220A and 220B are passed through amplifier 381 and mixer 382, and then into VGA output gain modulator 383. The Vtarget voltage inputs 240A and 240B are passed through the Vtarget current gain modulator 386, and rectified by rectifier 360 to produce VGA detector output 388.

FIG. 4B is a functional block diagram illustrating an alternative view of VGA detector 230. FIG. 4B depicts the VGA detector 230 with VGA outputs 220A and 220B, the amplifier 381, the mixing detector module 385, the Vtarget current gain modulator 386, and the VGA detector output 388 A and B. The amplifier 381 includes resistor 400 and 410, cascode transistor 405, and amplifier tail current 420. The mixing detector module 385 includes resistor 430 and 440, degenerated resistor 450, and mixing detector tail currents 460 and 470. The Vtarget current gain modulator 386 includes degenerator resistor 480, and tail currents 490 and 495. In a preferred embodiment, the VGA detector 230 is a rectifier made with self-mixing. The VGA outputs 220A and 220B of the VGA detector 230 is mixed with its own amplified signal. In a related embodiment. when the output of the mixing detector module 385 compensates an offset generated by the Vtarget current gain modulator 386, the swing control loop output 207 is set to a desired value. The ideal factor is 1 for non-return-to-zero signals. The ideal factor for phase-amplitude-modulation signals is 0.65. Given the limitations of a high-speed system, the present invention contemplates that the theoretical scaling factors can fall under the ideal factors.

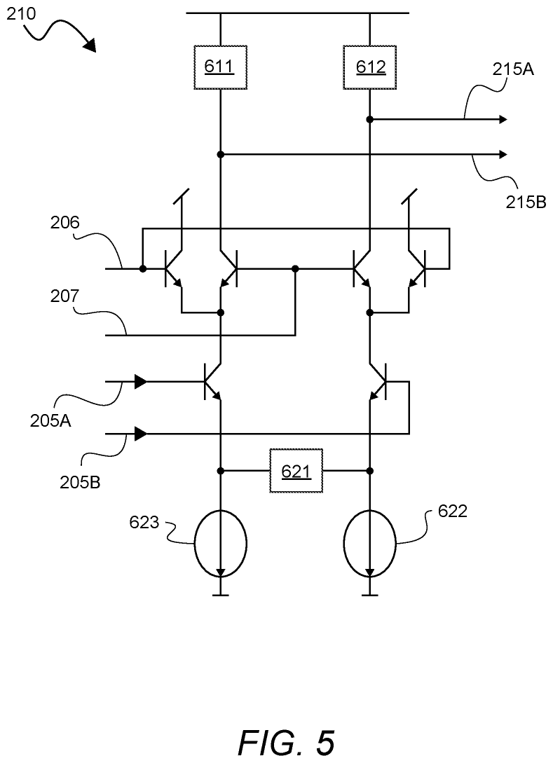

FIG. 5 is a functional block diagram illustrating the VGA 210 of the inventive subject matter. FIG. 5 depicts the VGA 210 with input voltage 205A and 205B, VGA control inputs 206 and 207, resistors 511 and 512, degenerated resistor 521, VGA tail currents 522 and 523, and VGA output voltage 215A and 215B. In the depicted embodiment of FIG. 4B, VGA outputs 220A and 220B is passed through amplifier 381 and mixer 385, and then into VGA output gain modulator 386. As shown in FIG. 4A, the Vtarget voltage inputs 240A and 240B are passed through the Vtarget current gain modulator 384, and rectified by rectifier 360 to produce VGA detector output 388. In a preferred embodiment, integrator 521 can produce a linear output. In one embodiment, integrator 521 can produce a linear output in an analog implementation. In another embodiment, integrator 521 can produce a linear output in a digital implementation.

The flowchart and block diagrams in the Figures illustrate the architecture, functionality, and operation of possible implementations of systems and methods according to various embodiments of the present invention. In this regard, each block in the flowchart or block diagrams may represent a module, a segment, or a portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

It should be apparent to those skilled in the art that many more modifications besides those already described are possible without departing from the inventive concepts herein. The inventive subject matter, therefore, is not to be restricted except in the scope of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Where the specification claims refers to at least one of something selected from the group consisting of A, B, C . . . and N, the text should be interpreted as requiring only one element from the group, not A plus N, or B plus N, etc.

What is claimed is:

1. A laser driver chipset for providing a signal to a laser diode comprising;
a variable gain amplifier (VGA) circuit configured to:
receive an input signal, wherein the input signal has a variable swing amplitude;
modulate the variable swing amplitude of the input signal to produce a fixed swing amplitude;
a laser driver circuit configured to:
receive a VGA output signal from the VGA circuit; and
generate a linear output response to the input signal such that it provides an output current to drive the laser diode.

2. The laser driver of claim 1, wherein the VGA circuit comprises a VGA coupled with:
a first loop for biasing the direct current level to a target direct current level, wherein the first loop comprises a common mode (CM) sensor and a first regulator; and
a second loop for modulating the variable swing amplitude of the input signal to produce a fixed swing amplitude, wherein the second loop comprises a detector and an integrator.

3. The laser driver of claim 2, wherein the VGA output signal comprises a combination of the biased direct current level and the fixed swing amplitude.

4. The laser driver of claim 2, wherein the CM sensor comprises two resistors, and a filtering capacitor.

5. The laser driver of claim 4, wherein the filtering capacitor is disposed between the two resistors.

6. The laser deriver of claim 4, wherein the first regulator receives a CM sensor output and a voltage reference to produce a first regulator output.

7. The laser driver of claim 5, wherein a first regulator output is configured to drive the VGA to match the reference voltage; and wherein the laser driver circuit sends the first regulator output to the VGA.

8. The laser driver of claim 2, wherein the detector comprises:
an amplifier that amplifies the VGA output;
a mixer that mixes the amplified VGA output with the VGA output to produce a mixed VGA output;
a rectifier that extracts a combination of the mixed VGA output and a voltage target to produce a detector output.

9. The laser driver of claim 8, wherein the detector sends the detector output to the integrator.

10. The laser driver of claim 8, further comprising an integrator;
wherein the integrator is configured to filter a high frequency energy of the detector output to produce a integrator output that is sent to the VGA.

11. The laser driver of claim 1, wherein the laser driver circuit comprises a DML driver that electrically couples with a cathode and an anode of the laser diode.

12. The laser driver of claim 11, wherein the laser driver circuit further comprises a pre-driver and a second regulator.

13. The laser driver of claim 12, wherein the pre-driver is configured to buffer the VGA output to produce a pre-driver output

14. The laser driver of claim 12, wherein the second regulator receives a drive tail current target and a drive tail current sensing.

15. The laser driver of claim 14, wherein the second regulator integrates the drive tail current target and the drive tail current sensing to produce a second regulator output that is sent to the buffer.

16. The laser driver of claim 1, wherein the laser diode is an edge emitting (ED) diode or a vertical-cavity surface-emitting laser (VCSEL) diode.

17. The laser driver of claim 1, wherein the input signal is a PAM4 signal.

18. The laser driver of claim 1, wherein the input signal is a NRZ signal.

19. The laser driver of claim 1, wherein the detector receives a voltage target from at least one of VCSEL, DML, and a EML target voltage generator.

20. The laser driver of claim 1, wherein the fixed swing amplitude is user-programmed.
